(19) United States
(12) Patent Application Publication
(10) Pub. No.: US 2012/0092003 A1
(43) Pub. Date: Apr. 19, 2012

(54) MAGNETIC-ELECTRIC ENERGY CONVERSION DEVICE, POWER SUPPLY DEVICE, AND MAGNETIC SENSOR

(75) Inventors: Masaaki Tanaka, Tokyo (JP); Pham Nam Hai, Tokyo (JP); Shinobu Ohya, Tokyo (JP); Stewart E. Barnes, Village of Palmetto Bay, FL (US); Sadamichi Maekawa, Ibaraki (JP)

(73) Assignees: Stewart E. Barnes, Village of Palmetto Bay, FL (US); TOHOKU UNIVERSITY, Sendai-shi, Miyagi (JP); THE UNIVERSITY OF TOKYO, Tokyo (JP)

(21) Appl. No.: 13/254,994

(22) PCT Filed: Mar. 6, 2010
(86) PCT No.: PCT/JP2010/053668

§ 371 Date: Dec. 23, 2011

Related U.S. Application Data
(60) Provisional application No. 61/158,129, filed on Mar. 6, 2009.

(51) Int. Cl. G01R 33/02; H01L 43/00

(52) U.S. Cl. 324/214; 310/308

(57) ABSTRACT

A magnetic-electric energy conversion device includes: a matrix (12) that includes ferromagnetic particles (10) with conductive properties; an injector (20) that injects carriers into the ferromagnetic particles; and a receptor (22) that accepts the carriers from the ferromagnetic particles. In the magnetic-electric energy conversion device, the carriers tunnel from the injector to the receptor via the ferromagnetic particles, when the magnetization state of the ferromagnetic particles is reversed by magnetic tunneling due to a magnetic field.

### TECHNICAL FIELD

The present invention relates to magnetic-electric energy conversion devices, power supply devices, and magnetic sensors, and more particularly, to a magnetic-electric energy conversion device, a power supply device, and a magnetic sensor that utilize an electromagnetic force generated due to a magnetic field, for example.

### BACKGROUND ART

According to the law of electromagnetic induction, an electromotive force is generated due to a temporal variation of a magnetic field. In recent years, a conversion element that converts the magnetic energy of a magnetostatic field into electric energy has been suggested (see Patent Literature 1, for example).

### [Patent Document]

Patent Literature 1: International Publication WO Pamphlet 2007-15475

### DISCLOSURE OF THE INVENTION

### Problems to Be Solved by the Invention

However, by the conversion element according to Patent Literature 1, the electromotive force generated by a conversion of the magnetic energy of a magnetostatic field into an electric energy lasts an extremely short period of time. Also, the magnitude of the electromotive force is as small as 100 μV/Tesla.

The present invention has been made in view of the above circumstances, and the object thereof is to enable generation of a long-lasting electromotive force.

### Means for Solving the Problems

The present invention provides a magnetic-electric energy conversion device that includes: a matrix that includes ferromagnetic particles with conductive properties; an injector that injects carriers into the ferromagnetic particles; and a receptor that accepts the carriers from the ferromagnetic particles, the carriers tunneling from the injector to the receptor via the ferromagnetic particles when the spins of the ferromagnetic particles are reversed by magnetic tunneling due to a magnetic field. According to the present invention, when the magnetization state of ferromagnetic particles is reversed by magnetic tunneling due to a magnetic field, carriers tunnel from the injector to the receptor via the ferromagnetic particles, so that a long-lasting electromotive force can be generated.

In the above structure, the matrix may be provided between the injector and the receptor.

The above structure may further include a barrier layer that is located at least between the matrix and the injector or between the matrix and the receptor, the barrier layer serving as the barrier for the carriers, the carriers being able to tunnel through the barrier layer.

In the above structure, the matrix and the ferromagnetic particles may be a single crystal.

In the above structure, the matrix may be GaAs, and the ferromagnetic particles may be zinc-blend-type MnAs.

In the above structure, the injector may inject carries spin-polarized in the same direction as the magnetic field, into the ferromagnetic particles.

In the above structure, the ferromagnetic particles may be nanoparticles.

The present invention provides a power supply device that includes the above magnetic-electric energy conversion device, and the power supply device supplies power through the electromotive force generated between the injector and the receptor.

The present invention provides a magnetic sensor that includes the above magnetic-electric energy conversion device, and the magnetic sensor senses the magnitude of the magnetic field through the electromotive force generated between the injector and the receptor.

The present invention provides a magnetic sensor that includes the above magnetic-electric energy conversion device, and the magnetic sensor senses the magnitude of the magnetic field through the magnetic resistance between the injector and the receptor.

### Effects of the Invention

The present invention enables long-time generation of an electromotive force.

### BRIEF DESCRIPTION OF THE DRAWINGS

FIG. 1 is a schematic cross-sectional view of a magnetic-electric energy conversion device according to an embodiment;

FIG. 2 is a diagram showing energy states of ferromagnetic particles;

FIG. 3 is a diagram for explaining electron conduction that occurs in a case where the spins of the ferromagnetic particles transit from a −S state to an S state;

FIG. 4 is a schematic view showing the magnetic field dependence of the spin electromotive force;

FIG. 5 is a schematic cross-sectional view of a magnetic-electric energy conversion device according to an example;

FIG. 6 is a TEM image obtained as a result of observation of a cross-sectional surface of the magnetic-electric energy conversion device;

FIG. 7 is a diagram showing a current I that flows when a voltage V is applied to the magnetic-electric energy conversion device

FIG. 8 is a diagram showing the time dependence of an electromotive force Vemf; and

FIG. 9 is a diagram showing a resistance R with respect to a magnetic field H.

### BEST MODES FOR CARRYING OUT THE INVENTION

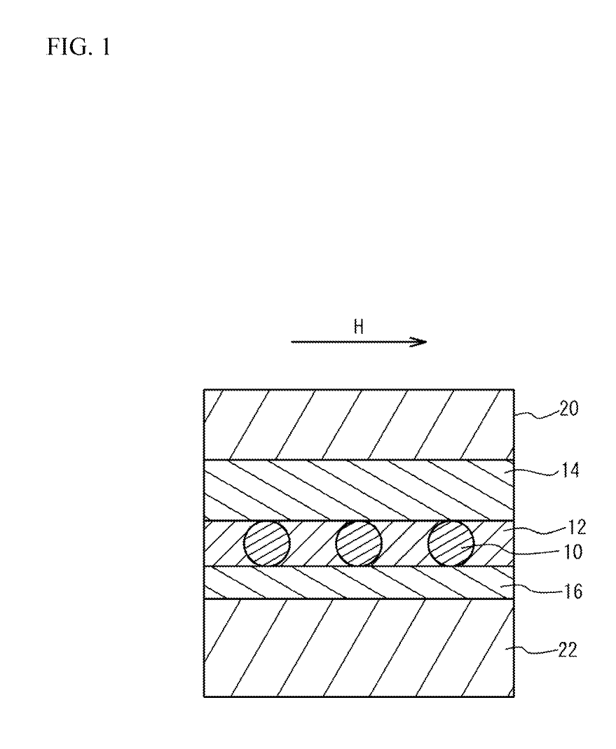

The following is a description of an embodiment of the present invention. FIG. 1 is a schematic cross-sectional view of a magnetic-electric energy conversion device according to the embodiment. A matrix 12 is provided between an injector 20 and a receptor 22 via tunnel barriers 14 and 16, respectively. Conductive ferromagnetic particles 10 are formed in the matrix 12. The injector 20 injects carriers such as electrons into the ferromagnetic particles 10. The receptor 22 accepts carriers from the ferromagnetic particles 10. The injector 20 and the receptor 22 are layers made of a conductive material such as a ferromagnetic metal, a nonmagnetic metal, or a degenerated semiconductor. The tunnel barrier 14 functions as a tunnel barrier when carriers are conducted from the injector 20 to the ferromagnetic particles 10. The tunnel barrier 16 functions as a tunnel barrier when carriers are conducted from the ferromagnetic particles 10 to the receptor 22. The tunnel barriers 14 and 16 can be layers having a larger bandgap than that of the matrix 2. Also, the tunnel barriers 14 and 16 may be schottky barriers appearing between the ferromagnetic particles 10 that are made of a metal and the matrix 12 that is a semiconductor.

The matrix 12 is a semiconductor or an insulator, for example, and at least has such insulation properties that carriers are always conducted from the injector 20 to the receptor 22 via the ferromagnetic particles 10. Also, the portions of the matrix 12 surrounding the ferromagnetic particles 10 preferably have insulation properties so that carriers can tunnel from the ferromagnetic particles 10 to the receptor 22. As the ferromagnetic particles 10, a ferromagnetic metal or a ferromagnetic half metal that is a ferromagnetic material and has conductive properties can be used. Also, the ferromagnetic particles preferably have a magnetic anisotropy.

The distance between the injector 20 and the ferromagnetic particles 10 is preferably such a distance that the carriers in the injector 20 can tunnel to the ferromagnetic particles 10. Likewise, the distance between the receptor 22 and the ferromagnetic particles 10 is preferably such a distance that the carriers in the ferromagnetic particles 10 can tunnel to the injector 20. Each of the ferromagnetic particles 10 preferably has such a size that the ferromagnetic particles 10 is in a magnetization state to allow magnetic tunneling. For example, the ferromagnetic particles 10 are preferably nanoparticles.

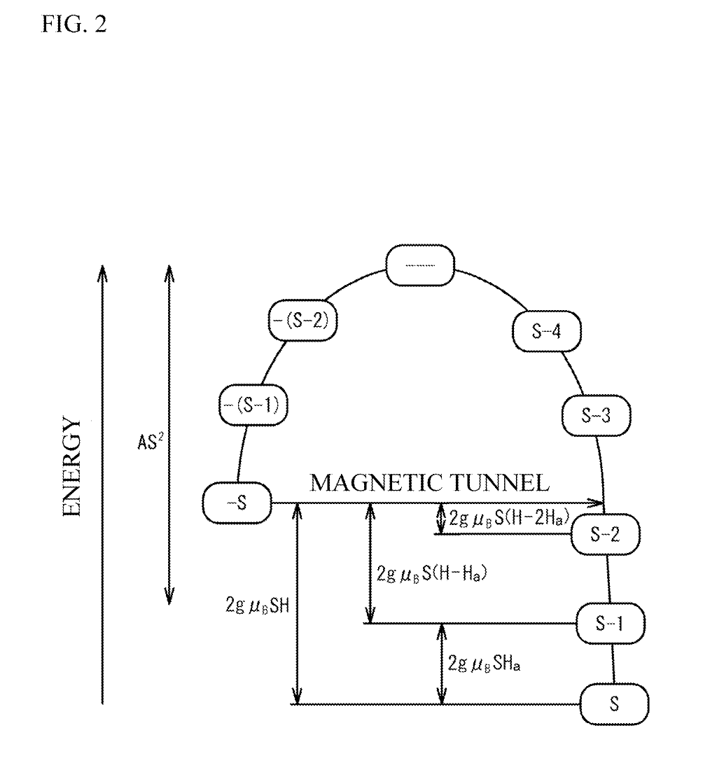

FIG. 2 shows energy states of the ferromagnetic particles 10. Specifically, FIG. 2 shows the energy states that appear in a case where a magnetic field H is applied in a horizontal direction. When the magnetic field H is applied, the magnetization in the ferromagnetic particles 10 is spin-splitted into an S state and a −S state. In the S state, the magnetic field direction is the same as the spin direction. In the −S state, the magnetic field direction is the opposite from the spin direction. The energy difference between the S state and the −S state (the Zeeman energy) is expressed as 2 gμ_{B}SH. Here, g represents the g factor, μ_{B} represents the magnetic permeability, S represents the spin moment of the ferromagnetic particles, and H represents the magnetic field. The ferromagnetic particles 10 have such a magnetic anisotropy that the magnetization in the direction of application of the magnetic field H is stabilized. Therefore, a magnetic barrier of AS² appears between the S state and the −S state. Here, A represents the coefficient indicative of uniaxial magnetic anisotropy.

Since the ferromagnetic particles 10 are as fine as several nanometers in diameter, the magnetization state is quantized from an S-1 state to an S-4 state and so on, and from a −(S-1) state to a −(S-2) state and so on. The energy difference from the level in a quantized adjacent portion (the energy difference between the S state and the S-1 state, for example) is 2 gμ_{B}SHa. Here, Ha represents A/gμ_{B}. In a case where the ferromagnetic particles 10 are extremely small, magnetic tunneling through the magnetic barrier occurs so that the magnetization state of the ferromagnetic particles 10 transits from the −S state to the S state.

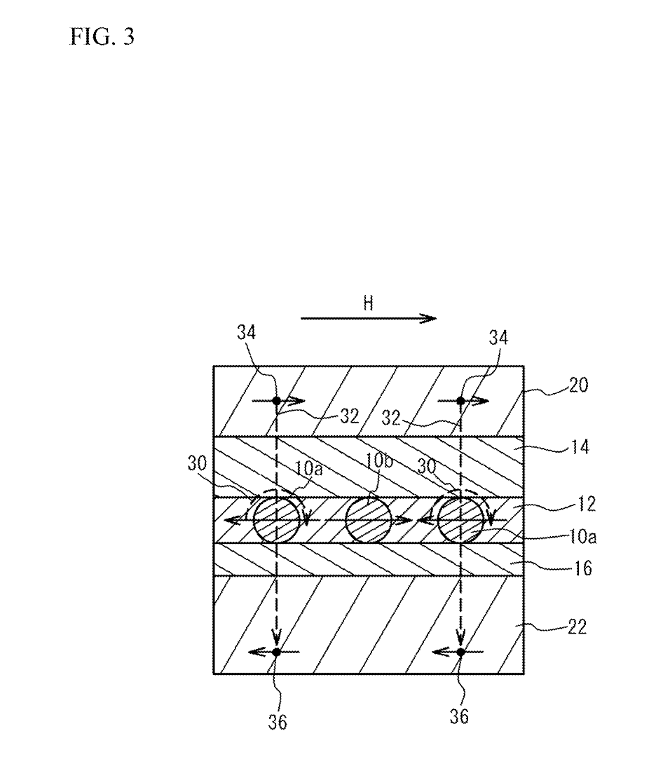

FIG. 3 is a diagram for explaining electron conduction that occurs in a case where the magnetization of the ferromagnetic particles 10 transits from the −S state to the S state. In practice, the magnetization might transit from the S state to the S-1 state or the S-2 state. In this description, however, the magnetization transits from the −S state to the S state, for ease of explanation. Among the ferromagnetic particles 10, a ferromagnetic particle 10b is magnetized in the magnetic field direction, and ferromagnetic particles 10a are magnetized in the opposite direction from the magnetic field H. That is, the magnetization of the ferromagnetic particles 10a is in the −S state shown in FIG. 2, and the magnetization of the ferromagnetic particles 10b is in the S state shown in FIG. 2. As indicated by arrows 30, when magnetic tunneling occurs so that the magnetization state of the ferromagnetic particles 10a transits from the −S state to the S state, tunneling conduction of carriers is caused via the tunnel barriers 14 and 16. In FIG. 3, spin electrons 34 having a magnetic moment in the same direction as the magnetic field H in the injector 20 tunnel through the tunnel barrier 14, and are conducted to the ferromagnetic particles 10a. Further the spin electrons 34 tunnel through the tunnel barrier 16, and are conducted to the receptor 22 (arrows 32). At this point, the spin magnetic moment of the electrons 34 that have reached the receptor 22 is reversed and directed in the opposite direction from the magnetic field. A potential difference equivalent to the energy difference between the −S state and the S state of the magnetization of the ferromagnetic particles 10 is generated between the injector 20 and the receptor 22. The potential difference is called a spin electromotive force.

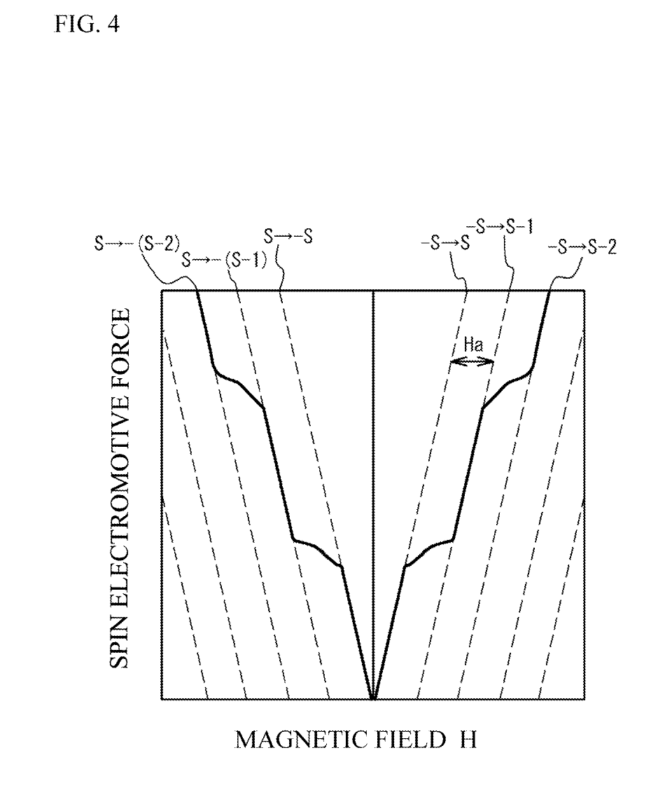

FIG. 4 is a schematic view showing the magnetic field dependence of the spin electromotive force. When the magnetic field H is small, the energy of the −S state is smaller than that of the S-1 state. In that case, the magnetization state of the ferromagnetic particles 10 transits from the −S state to the S state due to magnetic tunneling. Therefore, a spin electromotive force of 2 gμ_{B}SH/e is generated. Where the magnetic field becomes greater, and the energy of the −S state falls between the energy of the S-1 state and the energy of the S-2 state, the magnetization state of the ferromagnetic particles 10 transits from the −S state to the S-1 state. Accordingly, a spin electromotive force of 2 gμ_{B}S(H-Ha)/e is generated. Likewise, where the energy of the −S state falls between the energy of the S-1 state and the energy of the S-2 state (equivalent to the situation illustrated in FIG. 3), the magnetization state of the ferromagnetic particles 10 transits from the −S state to the S-2 state due to magnetic tunneling. Accordingly, a spin electromotive force of 2 gμ_{B}S(H-2Ha)/e is generated. The same applies to a case where the magnetic field H is applied in the opposite direction. In this manner, as the magnetic field becomes greater, the spin electromotive force behaves so as to transit to another branch, as shown in FIG. 4.

As described above, according to this embodiment, when the magnetization state of the ferromagnetic particles 10 is reversed by magnetic tunneling due to a magnetic field, carriers tunnel from the injector 20 to the receptor 22 via the ferromagnetic particles 10. Accordingly, the magnetic energy of a magnetostatic field can be converted into electric energy. Also, the time constant of magnetic tunneling can be made as long as 100 seconds or longer. Therefore, the electromotive force generated by a magnetostatic field can be maintained for a longer period of time than that of Patent Literature 1. Also, the magnitude of the electromotive force is S times as large as that of Patent Literature 1. For example, where S is approximately 200, the electromotive force reaches 20 mV/Tesla.

A barrier layer (the tunnel barrier 14 or 16, for example) that can serve as a barrier for carriers and allow carriers to tunnel therethrough is preferably provided at least between the matrix 12 and the injector 20 or between the matrix 12 and the receptor 22, so that carriers conducted to the receptor 22 do not return to the injector 20. Also, a Coulomb blockade effect is used so that the carriers do not return to the injector 20 via the ferromagnetic particles 10. Therefore, the ferromagnetic particles 10 are preferably nanoparticles. The size (the diameter, for example) of the ferromagnetic particles 10 are preferably several nanometers.

The following is a description of examples of this embodiment.

### Embodiment

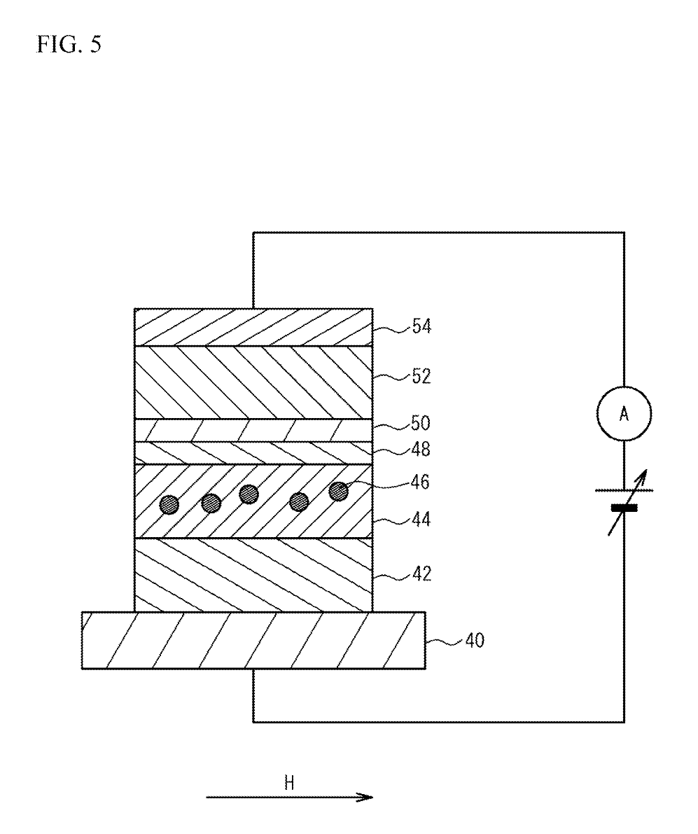

FIG. 5 is a schematic cross-sectional view of a magnetic-electric energy conversion device according to an example. As shown in FIG. 5, a Be-doped p-type GaAs layer 42 is formed on the (001) plane of a p-type GaAs substrate 40 by MBE (Molecular Beam Epitaxy) at a substrate temperature of 580° C. The film thickness of the p-type GaAs layer 42 is 20 nm.

After the p-type GaAs layer 42 is grown, the substrate temperature is lowered to 240° C., and a 10-nm thick Ga_{0.94}Mn_{0.06}As layer is formed on the p-type GaAs layer 42. An AlAs barrier layer 48 is formed on the Ga_{0.94}Mn_{0.06}As layer by MBE. The film thickness of the AlAs barrier layer 48 is 2.1 nm. A GaAs spacer layer 50 is formed on the AlAs barrier layer 48 by MBE. The film thickness of the GaAs spacer layer 50 is 1 nm. After that, the substrate temperature is increased to 480° C. in the MBE chamber, and a 20-minute heat treatment is performed. Through the treatment, a GaAs matrix layer 44 containing MnAs ferromagnetic particles 46 is formed from the Ga_{0.94}Mn_{0.06}As layer. The film thickness of the GaAs matrix layer 44 is 10 nm. The ferromagnetic particles 46 are MnAs having a zinc-blend-type crystal structure, and are approximately 2 to 3 nm in diameter.

A MnAs ferromagnetic layer 52 is formed on the GaAs spacer layer 50 by using MBE. The film thickness of the MnAs ferromagnetic layer 52 is 20 nm, and has a NiAs hexagonal crystal structure. An Au electrode is formed on the MnAs ferromagnetic layer 52. The structure extending from the Au electrode 54 to the p-type GaAs layer 42 has a cylindrical mesa-like shape, and the radius of the cylindrical structure is 100 μm. The side faces of the mesa are covered with an insulating film.

In FIG. 5, the MnAs ferromagnetic layer 52 and the Au electrode 54 are equivalent to the injector 20 of the embodiment, for example. The AlAs barrier layer 48 is equivalent to the tunnel barrier 14 of the embodiment, for example. The schottky barrier of the MnAs ferromagnetic particles 46 and the GaAs matrix layer 44 is equivalent to the tunnel barrier 16 of the embodiment, for example. The GaAs substrate 40 and the p-type GaAs layer 42 are equivalent to the injector 20 of the embodiment, for example.

When a 480° C. heat treatment is performed at 550° C. or higher, the MnAs ferromagnetic particles 46 become a NiAs crystal structure, but does not become a zinc-blend-type crystal structure. Also, the GaAs spacer layer 50 is preferably provided to increase the film quality of the MnAs ferromagnetic layer 52.

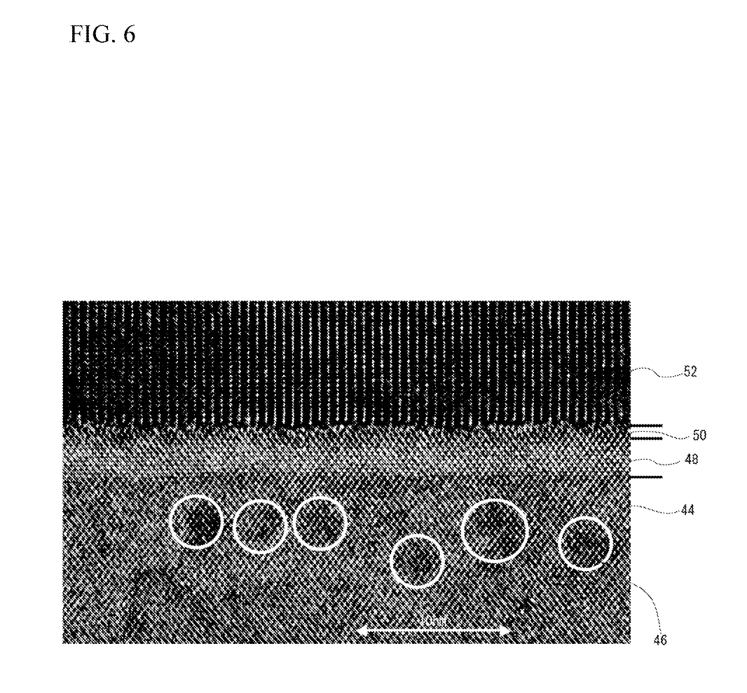

FIG. 6 is a TEM (Transmission Electron Microscope) image showing a cross-sectional surface of the magnetic-electric energy conversion device. The MnAs ferromagnetic particles 46 are observed in the GaAs matrix layer 44. The GaAs matrix layer 44 and the MnAs ferromagnetic particles 46 are the same single crystal, and form a zinc-blend-type crystal structure. The MnAs ferromagnetic particles 46 are 2 to 3 nm in diameter.

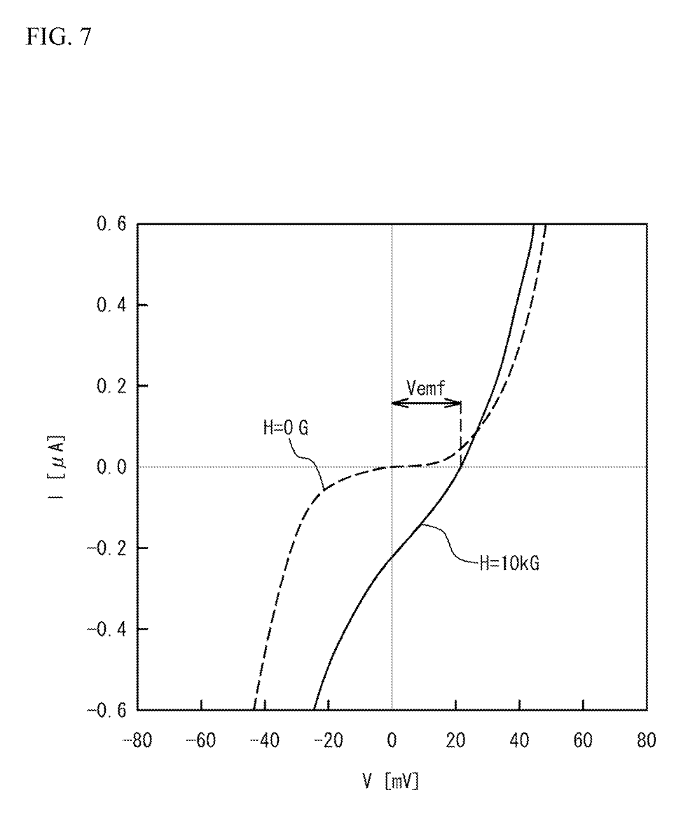

FIG. 7 is a diagram showing the current I that flows when a voltage V is applied to the magnetic-electric energy conversion device. The voltage V is applied between the Au electrode 54 and the GaAs substrate 40, as in FIG. 5. In FIG. 7, the dashed line indicates the current-voltage characteristics that appear when the magnetic field H is 0 G, and the solid line indicates the current-voltage characteristics that appear when the magnetic field H is 10 kG. The temperature at which the measurement is carried out is 3 K. When a magnetic field is not applied, current hardly flows, and the device resistance is extremely high in the vicinity of the point where the voltage V is 0 V. This is because the ferromagnetic particles 46 are extremely small, and a Coulomb blockade effect is caused to restrain successive tunneling conduction of electrons into the ferromagnetic particles 46 by tunneling conduction. To cause successive tunneling conduction of electrons, an energy of approximately 50 meV is required in a case where the ferromagnetic particles 46 are 2 nm in diameter, for example. When the voltage becomes approximately 50 mV, the current I becomes very high. That is, the resistance becomes very low.

In FIG. 7, when the magnetic field H is 10 kG, the voltage Vemf at which the current I is 0 is 21 mV. The voltage Vemf is the spin electromotive force that is generated based on the above described principles. Where the voltage Vemf is 2 gμ_{B}SH/e, the magnetic moment S of the ferromagnetic particles 46 is approximately 200.

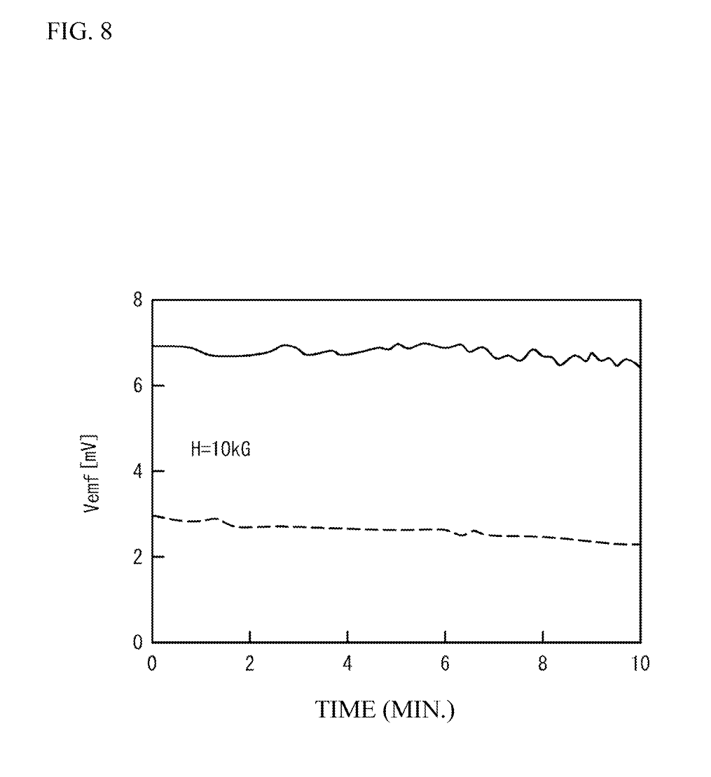

FIG. 8 is a diagram showing the time dependence of the electromotive force Vemf. The diagram shows the spin electromotive force Vemf generated after a magnetostatic field H of 10 kG is applied. The temperature at which the measurement is carried out is 3 K. The solid line represents a case where the structure between the Au electrode 54 and the GaAs substrate 40 is opened, and the dashed line represents a case where a load resistance of 200 kΩ is connected between the Au electrode 54 and the substrate 40. As shown in FIG. 8, the electromotive force is maintained for 10 or more minutes both in the case where it is opened between the electrodes and in the case where a load resistance is connected between the electrodes.

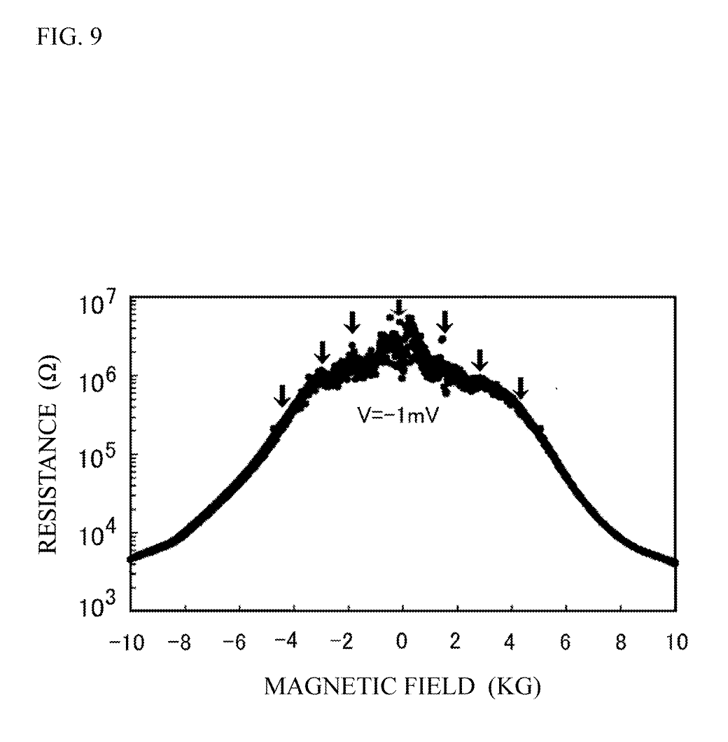

FIG. 9 is a diagram showing a resistance R with respect to the magnetic field H. The applied voltage V is −1 mV. The temperature at which the measurement is carried out is 3 K. In the vicinity of the point where the magnetic field is 0 G, the resistance is extremely high due to the above described Coulomb blockage effect. On the other hand, when the magnetic field H is applied, the electromotive force Vemf is generated as shown in FIG. 7, and the resistance in the vicinity of the point where the voltage is 0 becomes lower. Therefore, the resistance ratio MR between 10 kG and 0 G in magnetic field H is approximately 1000, as shown in FIG. 9. The step structure of the resistance R is observed with the magnetic field H indicated by arrows. This is the step equivalent to a magnetic tunnel from the −S state to an S-n state or a magnetic tunnel from the S state to a −(S-n) state in FIG. 2.

In the example, the matrix layer 44 and the ferromagnetic particles 46 are one single crystal, or a single zinc-blend-type crystal, for example. With this structure, the coupling between spins and electrons is strong. Also, a co-tunneling phenomenon to simultaneously cause spin-state magnetic tunneling and carrier tunneling easily occurs as described with reference to FIG. 3, and the magnetic energy is readily converted into an electric energy. If the coupling between spins and electrons is weak, the magnetic energy is converted into a thermal energy.

Particularly, the matrix layer 44 and the ferromagnetic particles 46 are preferably a III-V semiconductor. With this arrangement, the matrix layer 44 and the ferromagnetic particles 46 can be readily formed as a single crystal. Further, the ferromagnetic particles 46 can be easily formed, as the matrix layer 44 is made of GaAs while the ferromagnetic particles 46 are made of MnAs. As the matrix layer, a compound semiconductor such as AlGaAs or an elementary semiconductor such as Si or Ge can be used. As the ferromagnetic particles 46, a metal such as Cr, As, Fe, or Co, or a compound ferromagnetic material can be used.

To generate a Coulomb blockade effect, the ferromagnetic particles 10 are preferably nanoparticles. The diameters of the ferromagnetic particles 10 are preferably 10 nm or smaller, and more preferably, 3 nm or smaller.

The injector 20 may be a ferromagnetic layer containing Fe or Co or the like, other than MaAs. Further, as described with reference to FIG. 1, the injector 20 may be made of a nonmagnetic material.

In the example, a power supply device that supplies power through the electromotive force Vemf generated between the Au electrode 54 and the GaAs substrate 40 (or between the injector 20 and the receptor 22 in the embodiment) can be provided. With the device, power can be supplied from a magnetostatic field.

Also, since the magnitude of the electromotive force Vemf is determined by the magnitude of the magnetic field H, a magnetic sensor that senses the magnitude of the magnetic field through the electromotive force Vemf generated between the Au electrode 54 and the GaAs substrate 40 can be provided. Accordingly, a magnetic sensor that senses the magnitude of a magnetic field, without applying a current with the use of an external power supply like a Hall element, can be provided.

Further, as shown in FIG. 9, a magnetic sensor that senses the magnitude of a magnetic field through the magnetoresistance between the Au electrode 54 and the GaAs substrate 40 can be provided. Accordingly, a magnetic sensor having an extremely high magnetoresistance ratio can be realized.

Although a preferred example of the present invention has been described, the present invention is not limited to the specific example, and various modifications and changes may be made to the example within the scope of the claimed invention.

### EXPLANATION OF REFERENCE NUMERALS

10 ferromagnetic particles

12 matrix

14, 16 tunnel barrier

20 injector

22 receptor

40 substrate

42 p-type GaAs layer

44 matrix layer

46 ferromagnetic particles

48 barrier layer

50 spacer layer

52 ferromagnetic layer

54 Au electrode

1. A magnetic-electric energy conversion device comprising:
a matrix that includes ferromagnetic particles with conductive properties;
an injector that injects carriers into the ferromagnetic particles; and
a receptor that accepts the carriers from the ferromagnetic particles,
the carriers tunneling from the injector to the receptor via the ferromagnetic particles, when a magnetization state of the ferromagnetic particles is reversed by magnetic tunneling due to a magnetic field.

2. The magnetic-electric energy conversion device as claimed in claim 1, wherein the matrix is provided between the injector and the receptor.

3. The magnetic-electric energy conversion device as claimed in claim 2, further comprising
a barrier layer that is located between the matrix and the injector and between the matrix and the receptor, the barrier layer serving as the barrier for the carriers, the carriers being able to tunnel through the barrier layer.

4. The magnetic-electric energy conversion device as claimed in claim 1, wherein the matrix and the ferromagnetic particles are one single crystal.

5. The magnetic-electric energy conversion device as claimed in claim 4, wherein the matrix is GaAs, and the ferromagnetic particles are zinc-blend-type MnAs.

6. The magnetic-electric energy conversion device as claimed in claim 1, wherein the injector injects carries spin-polarized in the same direction as the magnetic field, into the ferromagnetic particles.

7. The magnetic-electric energy conversion device as claimed in claim 1, wherein the ferromagnetic particles are nanoparticles.

8. A power supply device comprising
the magnetic-electric energy conversion device including:
a matrix that includes ferromagnetic particles with conductive properties;
an injector that injects carriers into the ferromagnetic particles; and
a receptor that accepts the carriers from the ferromagnetic particles,
the carriers tunneling from the injector to the receptor via the ferromagnetic particles, when a magnetization state of the ferromagnetic particles is reversed by magnetic tunneling due to a magnetic field,
the power supply device supplying power through an electromotive force generated between the injector and the receptor.

9. A magnetic sensor comprising
the magnetic-electric energy conversion device including:
a matrix that includes ferromagnetic particles with conductive properties;
an injector that injects carriers into the ferromagnetic particles; and
a receptor that accepts the carriers from the ferromagnetic particles,
the carriers tunneling from the injector to the receptor via the ferromagnetic particles, when a magnetization state of the ferromagnetic particles is reversed by magnetic tunneling due to a magnetic field,
the magnetic sensor sensing a magnitude of the magnetic field through an electromotive force generated between the injector and the receptor.

10. A magnetic sensor comprising
the magnetic-electric energy conversion device including:
a matrix that includes ferromagnetic particles with conductive properties;
an injector that injects carriers into the ferromagnetic particles; and
a receptor that accepts the carriers from the ferromagnetic particles,
the carriers tunneling from the injector to the receptor via the ferromagnetic particles, when a magnetization state of the ferromagnetic particles is reversed by magnetic tunneling due to a magnetic field,
the magnetic sensor sensing a magnitude of the magnetic field through a magnetic resistance between the injector and the receptor.
